(19) United States
(12) Patent Application Publication
(10) Pub. No.: US 2026/0096369 A1
(43) Pub. Date: Apr. 2, 2026

(54) CHIP PRODUCTION METHOD

(71) Applicant: DISCO CORPORATION, Tokyo (JP)

(72) Inventor: Kazuki HASHIMOTO, Tokyo (JP)

(21) Appl. No.: 19/341,556

(22) Filed: Sep. 26, 2025

(30) Foreign Application Priority Data
Oct. 2, 2024 (JP) 2024-172949

(51) Int. Cl. H01L 21/78; H01L 21/268; H01L 21/683; H01L 23/544

(52) U.S. Cl. CPC H10P 54/00; H10P 34/42; H10P 72/7402; H10W 46/00; H10P 72/742; H10P 72/7422; H10W 46/503

(57) ABSTRACT

A chip production method in which a workpiece having a plurality of planned dividing lines set on a side of a front surface of a substrate and a functional layer formed on the front surface is divided along the planned dividing lines to produce chips, includes: applying a laser beam along the planned dividing lines to remove respective parts of the functional layer and form, in the substrate, respective processed grooves having a depth smaller than a finished thickness; processing a side of a back surface of the substrate to thin the substrate to the finished thickness; and after the processing, imparting an external force to the workpiece to divide the workpiece into a plurality of chips along the processed grooves.

### CROSS-REFERENCE TO RELATED APPLICATIONS

This application is based on and claims priority under 35 USC 119 from Japanese Patent Application No. 2024-172949 filed on Oct. 2, 2024, the contents of which are incorporated herein by reference.

### TECHNICAL FIELD

The present disclosure relates to a chip production method for producing a chip by dividing a workpiece along a planned dividing line.

### BACKGROUND ART

When a semiconductor wafer is subjected to thinning to produce chips, a production method with high yield is required to prevent wafer cracks from occurring when a thinner wafer is handled after the wafer is subjected to thinning.

Therefore, Patent Literature 1 describes the following production method. First, a dividing groove having a predetermined depth is formed by a cutting blade along a planned dividing line from a front surface of a wafer, and then the front surface of the wafer is covered with a protective member. Next, a back surface of the wafer is ground to expose the dividing groove, thereby dividing the wafer into chips. Then, after an adhesive film is uniformly attached to the back surface of the wafer divided into chips, a laser beam is applied to the adhesive film along the dividing groove to break the adhesive film.

According to this method, since the wafer is divided into chips when the wafer is subjected to thinning, cracks may occur in units of chips, but cracks will not occur on the wafer.
Patent Literature 1: JP2005-19525A

### SUMMARY OF INVENTION

However, this method requires a width of the cutting blade to be a width of the dividing groove, and cuts called chipping may occur on the front surface. Therefore, it is difficult to meet the demand for increasing the number of device chips to be obtained by narrowing the planned dividing line.

Therefore, in a chip production method in which a workpiece is divided along a planned dividing line to produce a chip, an object is to provide a method for increasing the number of device chips to be obtained by narrowing the planned dividing line while reducing cracks during wafer thinning.

The present disclosure provides a chip production method capable of narrowing a planned dividing line while reducing cracks during wafer thinning.

According to an aspect of the present disclosure, there is provided a chip production method in which a workpiece having a plurality of planned dividing lines set on a front surface of a substrate and a functional layer formed on the front surface is divided along the planned dividing lines to produce chips, the chip production method including:
a processed groove forming step of applying a laser beam along the planned dividing lines to remove respective parts of the functional layer and form, in the substrate, respective processed grooves having a depth smaller than a finished thickness;
a thinning step of processing a back surface of the substrate to thin the substrate to the finished thickness; and
a dividing step of imparting an external force to the workpiece to divide the workpiece into a plurality of chips along the processed grooves after the thinning step.

### BRIEF DESCRIPTION OF DRAWINGS

FIG. 1 is a flowchart illustrating an example of a process of a method for producing a chip 11.

FIGS. 2A and 2B are diagrams illustrating an example of a workpiece 1, in which FIG. 2A is a perspective view of the workpiece 1 and FIG. 2B is a cross-sectional view of the workpiece 1.

FIG. 3 is a diagram illustrating a laser-processed groove forming step S1.

FIG. 4 is a diagram illustrating processed grooves 16 formed in the laser-processed groove forming step S1.

FIG. 5 is a diagram illustrating a front surface protective sheet attaching step S2.

FIG. 6 is a diagram illustrating the workpiece 1 to which a front surface protective sheet 3 is attached in the front surface protective sheet attaching step S2.

FIG. 7 is a diagram illustrating a thinning step S3.

FIG. 8 is a diagram illustrating the workpiece 1 made thinner in the thinning step S3.

FIG. 9 is a diagram illustrating a film fixing step S4.

FIG. 10 is a diagram illustrating the workpiece 1 to which a die attach film 6 is fixed in the film fixing step S4.

FIG. 11 is a diagram illustrating a front surface protective sheet removing step S5.

FIG. 12 is a diagram illustrating a dividing step S6.

FIG. 13 is a diagram illustrating a state in which an external force is imparted to the workpiece 1 in the dividing step S6.

FIG. 14 is a diagram illustrating a state in which the workpiece 1 is divided in the dividing step S6.

### DESCRIPTION OF EMBODIMENTS

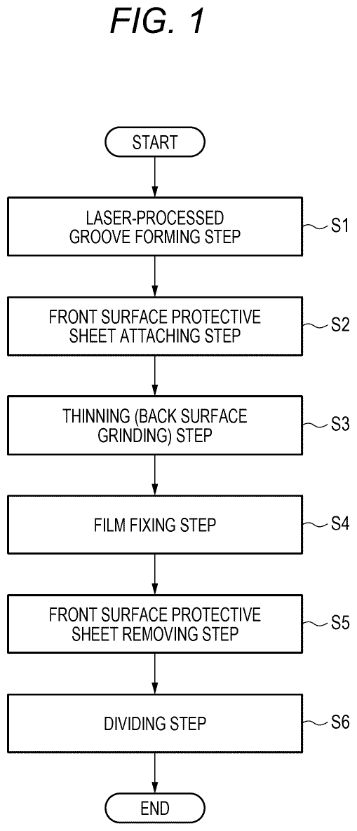

Hereinafter, an embodiment of the present disclosure will be described with reference to FIGS. 1 to 14.

### (Chip Production Method)

FIG. 1 is a flowchart illustrating an example of a process of a method for producing a chip 11.

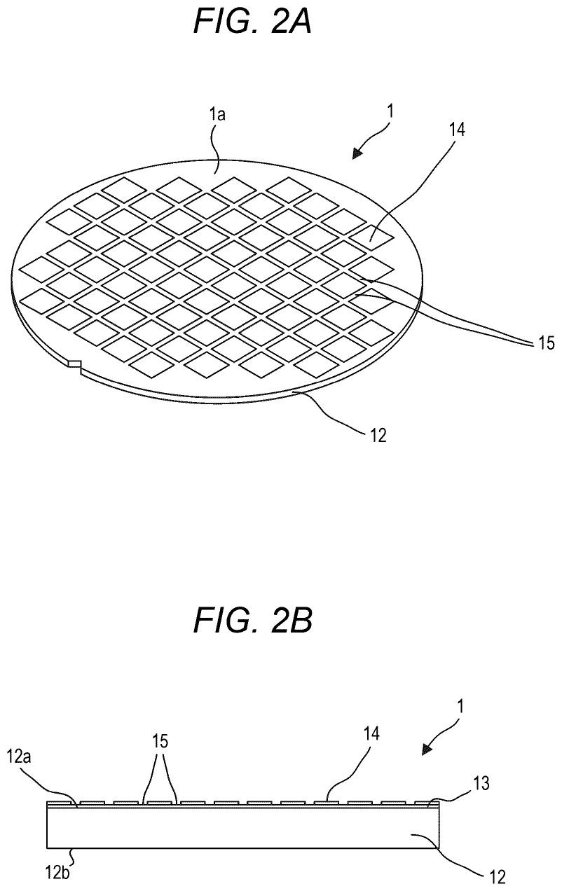

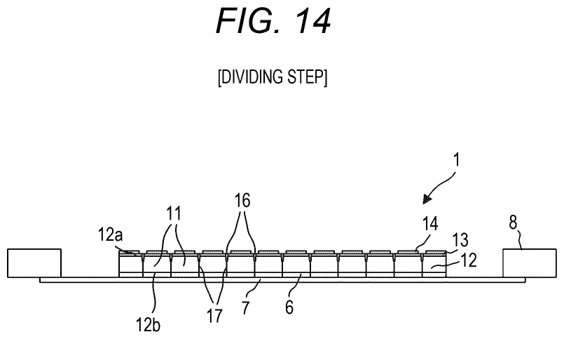

The method for producing the chip 11 (see FIG. 14) according to the embodiment of the present disclosure is a method for producing the chip 11 by dividing the workpiece 1 (see FIG. 2), and includes, as illustrated in FIG. 1, a laser-processed groove forming step S1, a front surface protective sheet attaching step S2, a thinning step S3, a film fixing step S4, a front surface protective sheet removing step S5, and a dividing step S6. The front surface protective sheet attaching step S2 and the front surface protective sheet removing step S5 may be omitted.

### (Workpiece)

FIG. 2A is a perspective view of the workpiece 1 and FIG. 2B is a cross-sectional view of the workpiece 1.

The workpiece 1 is, for example, a substantially disk-shaped wafer or optical device wafer made of silicon (Si), silicon carbide (SiC), gallium nitride (GaN), gallium arsenide (GaAs), or other semiconductor materials. The workpiece 1 may be various plate-shaped processing materials such as a plate-shaped inorganic material substrate of ceramics, glass, or sapphire, or a plate-shaped ductile material such as metal or resin. The workpiece 1 may be a package substrate or the like including a plurality of device chips sealed with mold resin or the like. FIG. 2 illustrates a wafer as an example of the workpiece 1.

The workpiece 1 illustrated in FIGS. 2A and 2B includes a substrate 12 made of silicon (Si) or the like, a functional layer 13 such as an oxide film, a nitride film, a low-k film, wiring, or a pattern formed on a front surface 12a of the substrate 12, and a device circuit 14 formed on a front surface of the functional layer 13. On a front surface 1a of the workpiece 1, a plurality of streets intersecting each other are defined as planned dividing lines 15, and a plurality of regions partitioned by the planned dividing lines 15 are formed in a grid pattern. The device circuit 14 such as an integrated circuit (IC), a large scale integrated circuit (LSI), or a micro electro mechanical system (MEMS) is formed in each of the regions partitioned by the planned dividing lines 15. When the workpiece 1 is divided along the planned dividing lines 15, individual chips 11 are formed. In the embodiment, each chip 11 has, for example, a square shape, but may have a rectangular shape.

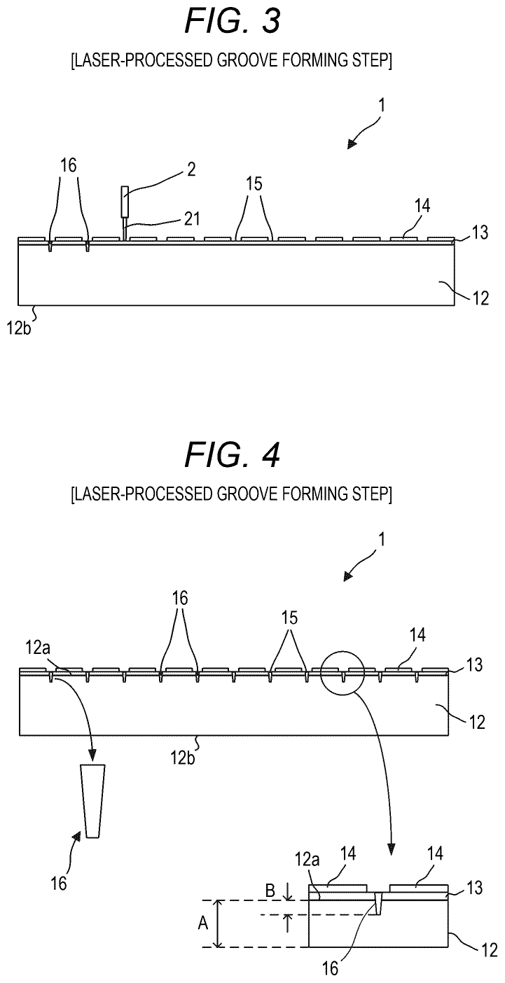

Next, steps S1 to S6 constituting the method for producing the chip 11 according to the embodiment of the present disclosure will be described with reference to FIGS. 3 to 14.

### (Laser-Processed Groove Forming Step S1)

FIG. 3 is a diagram illustrating the laser-processed groove forming step S1, and FIG. 4 is a diagram illustrating processed grooves 16 formed by the laser-processed groove forming step S1.

As illustrated in FIGS. 3 and 4, the laser-processed groove forming step S1 is a step of applying a laser beam 21 along the planned dividing lines 15 to remove respective parts of the functional layer 13 and form the processed grooves 16 having a depth B smaller than a finished thickness A in the substrate 12. For example, as illustrated in FIG. 3, after a laser application unit 2 is set at a predetermined interval from the front surface 1a of the workpiece 1 and a focal point of the laser beam 21 to be emitted from the laser application unit 2 is set, the laser beam 21 is emitted from the laser application unit 2 toward the planned dividing lines 15 while the laser application unit 2 or the workpiece 1 is relatively moved along the planned dividing lines 15, thereby forming the processed grooves 16.

As illustrated in FIG. 4, in the laser-processed groove forming step S1, each processed groove 16 is formed such that a groove width formed on a back surface 12b of the substrate 12 is smaller than a groove width formed on the front surface 12a of the substrate 12. For example, in the laser-processed groove forming step S1 of the present embodiment, laser application is performed a plurality of times on the same planned dividing line 15, and the focal point of the laser beam 21 is gradually deepened from the front surface 12a of the substrate 12, thereby forming an inverted triangular or inverted trapezoidal processed groove 16. With the processed groove 16 having such a shape, the chips 11 can be easily divided in the dividing step S6. The reason will be described later.

When the finished thickness of the substrate 12 is defined as A and the depth of the processed groove 16 from the front surface 12a of the substrate 12 is defined as B, in the laser-processed groove forming step S1, it is desirable to form the processed groove 16 such that B≥A×0.1 is satisfied.

For example, if the finished thickness A of the workpiece 1 is 60 μm, a thickness of the functional layer 13 is 30 μm, and the finished thickness A of the substrate 12 is 30 μm, the depth B of the processed groove 16 formed in the substrate 12 must be 3 μm or more, otherwise it will be difficult to divide the chips 11 in the dividing step S6. If the finished thickness A of the workpiece 1 is 60 μm, the thickness of the functional layer 13 is 40 μm, and the finished thickness A of the substrate 12 is 20 μm, the depth B of the processed groove 16 formed in the substrate 12 must be 2 μm or more, otherwise it will be difficult to divide the chips 11 in the dividing step S6. If the finished thickness A of the workpiece 1 is 60 μm, the thickness of the functional layer 13 is 10 μm, and the finished thickness A of the substrate 12 is 50 μm, the depth B of the processed groove 16 formed in the substrate 12 must be 5 μm or more, otherwise it will be difficult to divide the chips 11 in the dividing step S6.

The deeper the processed groove 16, the easier it is to divide the chips 11 in the dividing step S6. However, if the processed groove 16 is deep, the longer it takes to perform the laser-processed groove forming step S1. Therefore, from the standpoint of productivity, it is preferable to satisfy B<A×0.5.

### (Front Surface Protective Sheet Attaching Step S2)

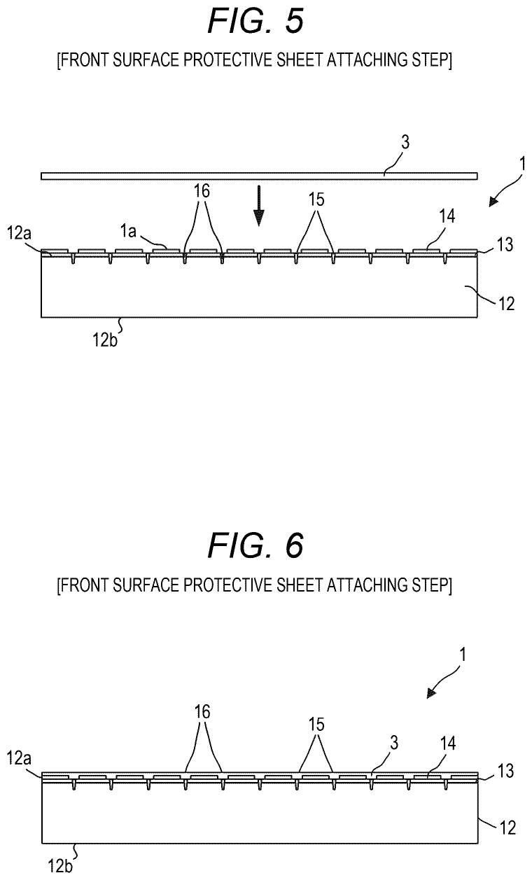

FIG. 5 is a diagram illustrating the front surface protective sheet attaching step S2, and FIG. 6 is a diagram illustrating the workpiece 1 to which a front surface protective sheet 3 is attached in the front surface protective sheet attaching step S2.

As illustrated in FIGS. 5 and 6, the front surface protective sheet attaching step S2 is a step of attaching, to the front surface 1a of the workpiece 1, the front surface protective sheet 3 that covers the functional layer 13. The front surface protective sheet 3 is not limited to a sheet material or an adhesive as long as the front surface protective sheet 3 can protect the front surface 1a of the workpiece 1 in the thinning step S3.

### (Thinning Step S3)

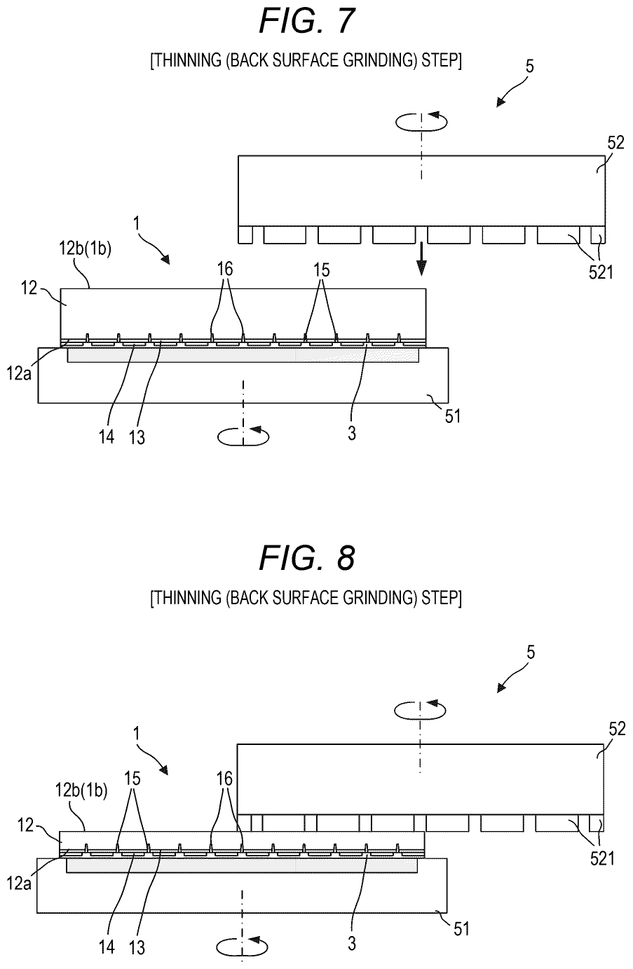

FIG. 7 is a diagram illustrating the thinning step S3, and FIG. 8 is a diagram illustrating the workpiece 1 made thinner in the thinning step S3.

As illustrated in FIGS. 7 and 8, the thinning step S3 is a step of thinning the substrate 12 to the finished thickness A by processing the back surface 12b of the substrate 12 after the laser-processed groove forming step S1 and the front surface protective sheet attaching step S2. For example, the thinning step S3 of the present embodiment is performed by a grinding device 5 including a holding table 51 and a grinding wheel 52. That is, the workpiece 1 is held on the holding table 51 with the back surface 1b facing upward, and the holding table 51 is rotated at a first set speed. While the grinding wheel 52 is rotated at a second set speed, grinding stones 521 provided on a lower surface of the grinding wheel 52 are brought into contact with the back surface 1b of the workpiece 1. Thus, the back surface 1b of the workpiece 1 is ground by a rotational speed difference between the holding table 51 and the grinding wheel 52, and the substrate 12 is thinned to the finished thickness A. The thinning step S3 is not limited to grinding, and may be performed by polishing, wet etching, dry etching, wafer splitting, or the like.

### (Film Fixing Step S4)

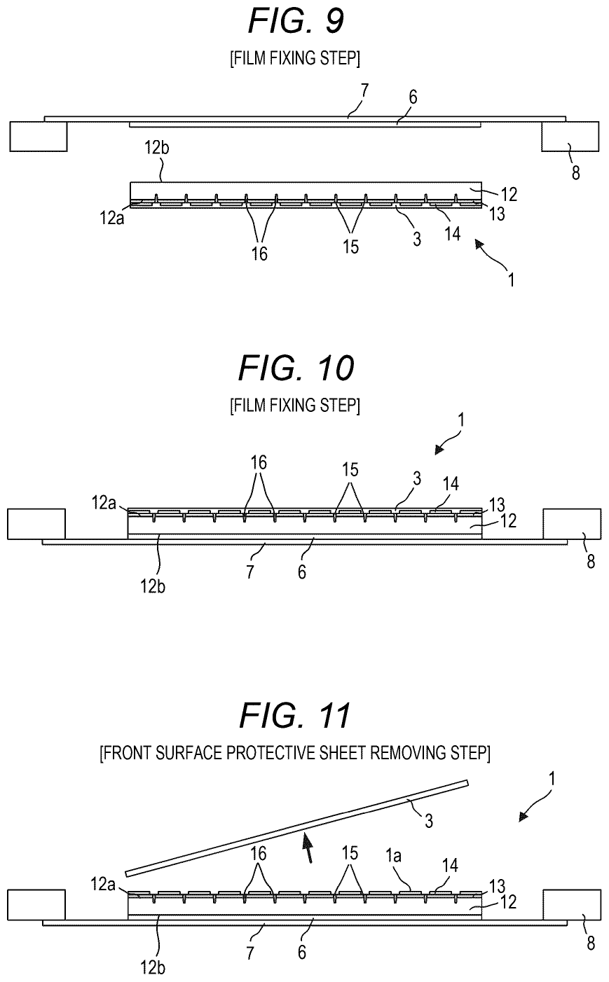

FIG. 9 is a diagram illustrating the film fixing step S4, and FIG. 10 is a diagram illustrating the workpiece 1 to which a die attach film 6 is fixed in the film fixing step S4.

As illustrated in FIGS. 9 and 10, the film fixing step S4 is a step of fixing the die attach film 6 to the back surface 12b of the substrate 12. The die attach film 6 is an adhesive film for die bonding, and functions as an adhesive when the workpiece 1 is divided into the chips 11 and then mounted on a lead frame, a mounting substrate, or the like.

In the film fixing step S4 of the present embodiment, the die attach film 6 is integrated with a dicing sheet 7 in advance, and the die attach film 6 is fixed to the back surface 12b of the substrate 12 while the die attach film 6 and the dicing sheet 7 are supported by a ring frame 8. The ring frame 8 is an annular plate member made of, for example, metal or resin and having an opening larger than an outer diameter of the workpiece 1. The dicing sheet 7 is an expandable sheet member having an outer diameter larger than the opening of the ring frame 8, and is attached to a back surface of the ring frame 8 so as to cover the opening of the ring frame 8. Thus, the workpiece 1 is supported by the ring frame 8 via the die attach film 6 and the dicing sheet 7.

### (Front Surface Protective Sheet Removing Step S5)

FIG. 11 is a diagram illustrating the front surface protective sheet removing step S5. As illustrated in FIG. 11, the front surface protective sheet removing step S5 is a step of removing the front surface protective sheet 3 from the front surface 1a of the workpiece 1 supported by the ring frame 8.

### (Dividing Step S6)

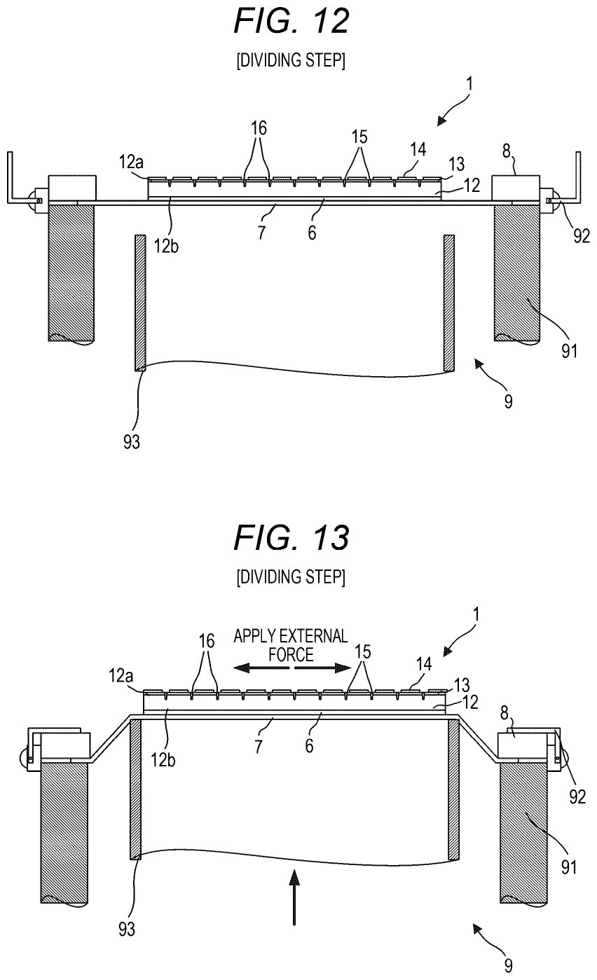

FIG. 12 is a diagram illustrating the dividing step S6, FIG. 13 is a diagram illustrating a state in which an external force is imparted to the workpiece 1 in the dividing step S6, and FIG. 14 is a diagram illustrating a state in which the workpiece 1 is divided in the dividing step S6.

As illustrated in FIGS. 12 to 14, the dividing step S6 is a step of imparting an external force to the workpiece 1 to divide the workpiece 1 into a plurality of chips 11 along the processed grooves 16. For example, an external force is imparted to the workpiece 1 based on an expanding process of stretching the dicing sheet 7, and the workpiece 1 is divided into a plurality of chips 11 by cracks 17 extending from the processed grooves 16 due to the external force. At this time, since each processed groove 16 is formed in an inverted triangle or an inverted trapezoid as described above, the external force promotes the extension of each crack 17, making it easier to divide the workpiece 1.

In the dividing step S6 of the present embodiment, an external force is imparted to the workpiece 1 including the die attach film 6 to divide the workpiece 1 into a plurality of chips 11 with the die attach film 6 attached. For example, the expanding process is performed in a frozen state at −10° C. That is, the dicing sheet 7 maintains its expandability even in a frozen state at −10° C., while the die attach film 6 becomes easily torn in a frozen state at −10° C. By utilizing this difference in physical properties, the die attach film 6 is also divided integrally with the chip 11 during the expanding process.

As illustrated in FIGS. 12 and 13, the dividing step S6 of the present embodiment is performed using an expanding device 9. The expanding device 9 includes cylindrical base portions 91 each having a mounting surface on which the ring frame 8 is mounted, clamp portions 92 that fix the ring frame 8 to the mounting surfaces of the base portions 91, and cylindrical expanding portions 93 that are disposed in the base portions 91, respectively, and press the dicing sheet 7 mounted on the ring frame 8 from below to expand the dicing sheet 7. The dividing step S6 is not limited to the expanding process of stretching the dicing sheet 7, and may be a breaking process of pressing and breaking the substrate 12 with a guillotine blade or the like.

According to such a method for producing the chip 11, a laser beam is applied to form, in the substrate 12, a processed groove 16 having a depth smaller than a finished thickness. Thus, a processed groove 16 narrower than a width of a cutting blade can be formed, and chipping can be reduced as compared with cutting blade processing. Therefore, it is possible to increase the number of chips 11 to be obtained by narrowing the planned dividing line 15 while reducing cracks during thinning of the substrate 12.

Although the embodiment of the present disclosure has been described above with reference to the drawings, it is needless to say that the present disclosure is not limited to that embodiment. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

For example, in the embodiment described above, after the processed groove 16 is formed in the laser-processed groove forming step S1, a wafer is ground in the thinning step S3 and divided into the chips 11 in the dividing step S6. However, the present disclosure is not limited thereto. After the wafer is ground in the thinning step S3, the processed groove 16 may be formed in the laser-processed groove forming step S1 and the wafer may be divided into the chips 11 in the dividing step S6.

The present specification describes at least the following matters. The components in parentheses correspond to those in the embodiment described above, but are not limited thereto.
(1) A chip production method in which a workpiece (workpiece 1) having a plurality of planned dividing lines (planned dividing lines 15) set on a front surface (front surface 12a) of a substrate (substrate 12) and a functional layer (functional layer 13) formed on the front surface is divided along the planned dividing lines to produce chips (chips 11), the chip production method including:
a processed groove forming step (laser-processed groove forming step S1) of applying a laser beam (laser beam 21) along the planned dividing lines to remove respective parts of the functional layer and form, in the substrate, respective processed grooves (processed grooves 16) having a depth smaller than a finished thickness;
a thinning step (thinning step S3) of processing a back surface (back surface 12b) of the substrate to thin the substrate to the finished thickness; and
a dividing step (dividing step S6) of imparting an external force to the workpiece to divide the workpiece into a plurality of chips along the processed grooves after the thinning step.

According to (1), the laser beam is applied to form, in the substrate, processed grooves having a depth smaller than a finished thickness. Thus, processed grooves narrower than a width of a cutting blade can be formed, and chipping can be reduced as compared with cutting blade processing. Therefore, it is possible to increase the number of device chips to be obtained by narrowing the planned dividing lines while reducing cracks during wafer thinning.
(2) The chip production method according to (1), in which in the processed groove forming step, each processed groove is formed such that a groove width formed on the back surface of the substrate is smaller than a groove width formed on the front surface of the substrate.

According to (2), when the wafer is divided into a plurality of chips in the dividing step, cracks are likely to extend.
(3) The chip production method according to (1) or (2), in which
when the finished thickness of the substrate is defined as A and a depth of the processed groove from the front surface of the substrate is defined as B, in the processed groove forming step, the processed groove is formed such that B≥A×0.1 is satisfied.

According to (3), when the wafer is divided into a plurality of chips in the dividing step, cracks are likely to extend.
(4) The chip production method according to any one of (1) to (3), in which
the thinning step is performed after the processed groove forming step.

According to (4), the number of cases a thin wafer needs to be handled can be reduced as compared with a case where the thinning step is performed before the processed groove forming step.
(5) The chip production method according to any one of (1) to (4), further including:
a fixing step (film fixing step S4) of fixing a die attach film (die attach film 6) to the back surface of the substrate after the thinning step, in which
in the dividing step, the external force is imparted to the workpiece including the die attach film to divide the workpiece into a plurality of chips with the die attach film attached.

According to (5), the die attach film for fixing the chips to a motherboard can be attached to the chips in a chip production stage, and the productivity is improved.
(6) The chip production method according to (4), further including:
a front surface protective sheet attaching step (front surface protective sheet attaching step S2) of attaching a front surface protective sheet (front surface protective sheet 3) that covers the functional layer formed on the front surface of the substrate after the processed groove forming step and before the thinning step; and
a front surface protective sheet removing step (front surface protective sheet removing step S5) of removing the front surface protective sheet after the thinning step and before the dividing step.

According to (6), the functional layer formed on the front surface of the substrate can be protected in the thinning step.

### REFERENCE SIGNS LIST

1 workpiece
11 chip
12 substrate
12a front surface of substrate
12b back surface of substrate
13 functional layer
15 planned dividing line
16 processed groove
21 laser beam
3 front surface protective sheet
6 die attach film
S1 laser-processed groove forming step (processed groove forming step)
S2 front surface protective sheet attaching step
S3 thinning step
S4 film fixing step
S5 front surface protective sheet removing step
S6 dividing step

What is claimed is:

1. A chip production method in which a workpiece having a plurality of planned dividing lines set on a side of a front surface of a substrate and a functional layer formed on the front surface is divided along the planned dividing lines to produce chips, the chip production method comprising:
applying a laser beam along the planned dividing lines to remove respective parts of the functional layer and form, in the substrate, respective processed grooves having a depth smaller than a finished thickness;
processing a side of a back surface of the substrate to thin the substrate to the finished thickness; and
after the processing, imparting an external force to the workpiece to divide the workpiece into a plurality of chips along the processed grooves.

2. The chip production method according to claim 1, wherein
in the applying of the laser beam, each of the processed grooves is formed such that a groove width of the each of the processed grooves on the side of the back surface of the substrate is smaller than a groove width of the each of the processed grooves on the side of the front surface of the substrate.

3. The chip production method according to claim 1, wherein
when the finished thickness of the substrate is defined as A and a depth of the processed grooves from the front surface of the substrate is defined as B, in the applying of the laser beam, the processed grooves are formed such that B≥A×0.1 is satisfied.

4. The chip production method according to claim 2, wherein
when the finished thickness of the substrate is defined as A and a depth of the processed grooves from the front surface of the substrate is defined as B, in the applying of the laser beam, the processed grooves are formed such that B≥A×0.1 is satisfied.

5. The chip production method according to claim 1, wherein
the processing to thin the substrate is performed after the applying of the laser beam.

6. The chip production method according to claim 2, wherein
the processing to thin the substrate is performed after the applying of the laser beam.

7. The chip production method according to claim 1, wherein
the applying of the laser beam is performed after the processing to thin the substrate, and
the imparting of the external force is performed after the applying of the laser beam.

8. The chip production method according to claim 2, wherein
the applying of the laser beam is performed after the processing to thin the substrate, and
the imparting of the external force is performed after the applying of the laser beam.

9. The chip production method according to claim 3, wherein
the processing to thin the substrate is performed after the applying of the laser beam.

10. The chip production method according to claim 4, wherein
the processing to thin the substrate is performed after the applying of the laser beam.

11. The chip production method according to claim 1, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

12. The chip production method according to claim 2, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

13. The chip production method according to claim 3, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

14. The chip production method according to claim 4, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

15. The chip production method according to claim 5, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

16. The chip production method according to claim 6, further comprising:
fixing a die attach film to the side of the back surface of the substrate after the processing to thin the substrate, wherein
in the imparting of the external force, the external force is imparted to the workpiece including the die attach film to divide the workpiece into a plurality of chips with the die attach film attached.

17. The chip production method according to claim 5, further comprising:
attaching a front surface protective sheet that covers the functional layer formed on the front surface of the substrate after the applying of the laser beam and before the processing to thin the substrate; and
removing the front surface protective sheet after the processing to thin the substrate and before the imparting of the external force.

18. The chip production method according to claim 6, further comprising:
attaching a front surface protective sheet that covers the functional layer formed on the front surface of the substrate after the applying of the laser beam and before the processing to thin the substrate; and
removing the front surface protective sheet after the processing to thin the substrate and before the imparting of the external force.
